(19) United States
(12) Patent Application Publication
(10) Pub. No.: US 2026/0011359 A1
(43) Pub. Date: Jan. 8, 2026

(54) POWER SAVING SCHEME FOR NON-RANK0 MEMORY DIES

(71) Applicant: Micron Technology, Inc., Boise, ID (US)

(72) Inventor: Jongtae KWAK, Carrollton, TX (US)

(21) Appl. No.: 19/206,174

(22) Filed: May 13, 2025

Related U.S. Application Data
(60) Provisional application No. 63/668,600, filed on Jul. 8, 2024.

(51) Int. Cl. G11C 11/4074; H10B 80/00

(52) U.S. Cl. CPC G11C 11/4074; H10B 80/00

(57) ABSTRACT

A memory die configurable into a first die configuration or a second die configuration, includes a logic circuit; a power amplifier configured to regulate, for the logic circuit, an external supply voltage to an internal supply voltage having a target voltage level; a shorting circuit configured to receive a control signal and enable or disable the power amplifier based on the control signal; and a control circuit configured to generate the control signal based on whether the memory die is configured in the first die configuration or the second die configuration, as indicated by a configuration mode signal. The control circuit may generate the control signal with an enabled signal level such that the power amplifier is enabled by the shorting circuit. The control circuit may generate the control signal with a disabled signal level such that the power amplifier is disabled by the shorting circuit.

### CROSS-REFERENCE TO RELATED APPLICATION

This patent application claims priority to U.S. Provisional Patent Application No. 63/668,600, filed on Jul. 8, 2024, entitled “POWER SAVING SCHEME FOR NON-RANKO MEMORY DIES,” and assigned to the assignee hereof. The disclosure of the prior application is considered part of and is incorporated by reference into this patent application.

### TECHNICAL FIELD

The present disclosure generally relates to memory devices, memory device operations, and, for example, to a power saving scheme for memory dies.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram of an example apparatus according to one or more implementations.

FIG. 2 is a diagram of an example memory device that may be manufactured using techniques described herein.

FIG. 3 is a schematic diagram of a memory die according to one or more implementations.

FIG. 4A is a schematic diagram of a control circuit of a memory die according to one or more implementations.

FIG. 4B is a schematic diagram of a control circuit of a memory die according to one or more implementations.

FIG. 4C is a schematic diagram of a control circuit of a memory die according to one or more implementations.

FIG. 4D is a schematic diagram of a control circuit of a memory die according to one or more implementations.

FIG. 4E is a schematic diagram of a control circuit of a memory die according to one or more implementations.

FIG. 5 is a flowchart of an example method associated with a power saving scheme for non-rank0 memory dies.

FIG. 6 is a diagram illustrating example systems in which the memory device described herein may be used.

### DETAILED DESCRIPTION

In the field of semiconductor memory devices, particularly three-dimensional (3D) stackable dynamic random-access memory (DRAM) known as 3DS DRAM configurations, multiple memory dies may be stacked and interconnected to form a high-density memory package. These 3DS DRAM configurations may involve communication between a memory controller and multiple layers of dies where typically only a “rank0” memory die interfaces directly with the memory controller, while the other “non-rank0” memory dies communicate indirectly with the memory controller via the rank0 memory die. However, this configuration presents certain challenges related to power consumption and efficiency.

In addition, memory dies may be arranged as standalone memory dies. For example, a memory die may be arranged in a non-stacked configuration, for example, when implemented in a single die package (SDP). The memory die arranged in a non-stacked configuration may also interface directly with the memory controller. However, memory dies of a same type, whether arranged in a stacked configuration or a non-stacked configuration, or whether implemented as a rank0 memory die or a non-rank0 memory die, are typically manufactured by the same manufacturing processes, with similar structures and components, in order to reduce manufacturing costs.

While each memory die may contain similar circuitry, not all circuits within the non-rank0 memory dies are used. In other words, some circuits within a memory die may be used only when the memory die interfaces directly with the memory controller. Thus, these circuits are used when a memory die is used as a rank0 memory die or when the memory die is used as a standalone memory die (e.g., when the memory die is not used in a memory stack or die stack). Nevertheless, these circuits continue to consume power in the form of leakage current (e.g., bias current), despite not being used. The leakage current of a memory stack may be equal to a leakage current of a single memory die multiplied by a number of dies in the memory stack, since each memory die may have a similar amount of leakage current. The leakage current becomes more significant when considering a memory module that may contain multiple memory stacks, leading to amplified power waste across the system.

For example, a DRAM die may include a power amplifier configured to regulate an external voltage down to a target level such that logic circuits that are supplied with this regulated internal voltage are immune to external voltage noise. Thus, the regulated internal voltage generated by the power amplifier may improve performance of the logic circuits at a cost of the power amplifier's bias current. However, the logic circuits may not be used in non-rank0 memory dies, rendering the power amplifier unnecessary in non-rank0 memory dies. Nevertheless, the logic circuits within non-rank0 memory dies, although not needed, may still need to be maintained in a defined state to avoid being in a floating state that can cause power losses through leakage. This unnecessary power consumption highlights a need for a power management scheme tailored to stacked memory configurations such as 3DS, thereby conserving power without compromising the operational stability of a memory stack.

Some implementations described herein optimize resource consumption in 3DS DRAM configurations by implementing power management techniques on inactive logic circuits. For example, a methodology may be employed where non-rank0 memory dies within a 3DS stack receive power management signals that selectively deactivate a power amplifier while maintaining logic circuits, that would otherwise be supplied by the power amplifier's regulated internal voltage, in a non-floating state. Such power control strategies may deactivate the power amplifiers on non-rank0 memory dies, thereby substantially reducing leakage currents and preventing unnecessary power losses.

One or more implementations may mitigate excessive power dissipation in standby circuits of 3DS DRAM stacks by selectively deactivating unnecessary power amplifiers within non-rank0 memory dies, curtailing leakage currents. This focused power management scheme may maintain inactive logic circuits in a power-conserving state, to avoid the inactive logic circuits being in a floating state and/or a creation of disruptive floating signals. Consequently, the power management scheme may lead to an increase in power efficiency of the memory stack, thereby conserving energy resources and enhancing the power integrity of electronic systems. Moreover, the initiative of reducing the energy profile of 3D memory configurations substantially benefits the energy sustainability of systems that employ these memory stacks, such as portable electronic devices, and contributes to the operational effectiveness of energy-intensive environments like data centers. In this way, one or more implementations may conserve processing resources, memory resources, network resources, and/or the like.

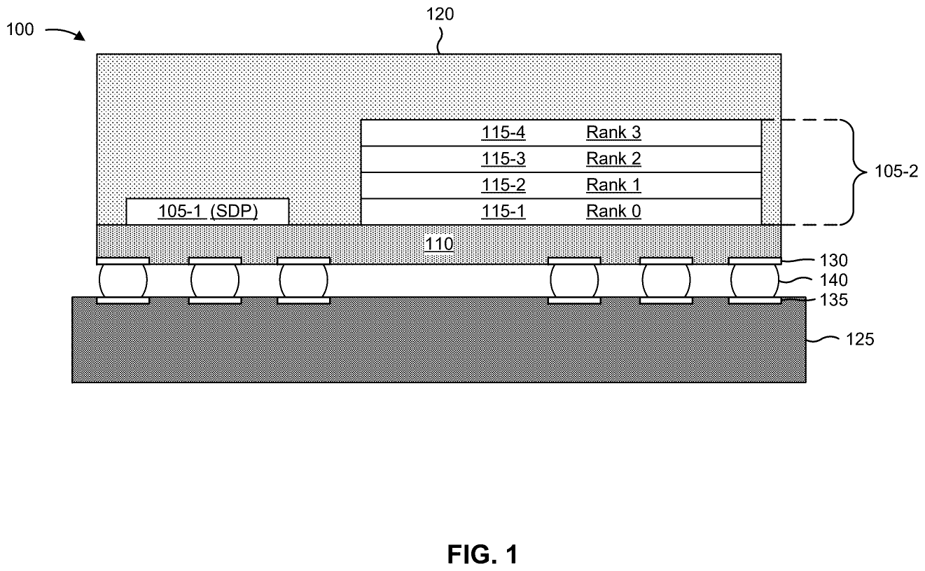

FIG. 1 is a diagram of an example apparatus 100 according to one or more implementations. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly. In some implementations, the apparatus 100 may be a double data rate (DDR) dual in-line memory module (DIMM).

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may be a single memory die (sometimes called a die), as shown by the first integrated circuit 105-1. In some implementations, the single memory die may be provided in an SDP as a standalone memory die. For example, the first integrated circuit 105-1 may be arranged in a non-stacked configuration. The first integrated circuit 105-1 may interface directly with a memory controller for receiving commands, such as read commands and/or write commands. The first integrated circuit 105-1 may be configured to decode a command received from the memory controller and perform an operation associated with the command. In addition, the first integrated circuit 105-1 may receive one or more programmed signals from the memory controller that place the first integrated circuit 105-1 into a particular programmed state. The one or more programmed signals may be fixed or fused signals. In addition, the first integrated circuit 105-1 may receive one or more operating mode signals from the memory controller that place the first integrated circuit 105-1 into a particular operating state. For example, the one or more operating mode signals may include a test mode signal that places the first integrated circuit 105-1 into an operating state for testing (e.g., a test mode), or may include a run mode signal that places the first integrated circuit 105-1 into a normal operating state. In addition, the first integrated circuit 105-1 may receive one or more configuration mode signals that place the first integrated circuit 105-1 into a particular configuration state.

In some implementations, an integrated circuit 105 may include multiple memory dies 115 (sometimes called dies), as shown by the second integrated circuit 105-2, which is shown as including four memory dies 115-1 through 115-4.

As shown in FIG. 1, for an integrated circuit 105 that includes multiple dies 115, the dies 115 may be stacked on top of each other to reduce a footprint of the apparatus 100. Thus, the dies 115 may form a memory stack or die stack. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including four dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. In addition, the first die 115-1 may be referred as a rank0 memory die. Thus, the first die 115-1 may be configured as having a first predefined die rank being a zero rank (e.g., rank 0). The second die 115-2 may be referred as a rank 1 memory die. The third die 115-3 may be referred as a rank 2 memory die. The fourth die 115-4 may be referred as a rank 3 memory die. The second die 115-2, the third die 115-3, and the fourth die 115-4 may be referred to as non-rank0 memory dies. Thus, the second die 115-2 may be configured as having a second predefined die rank being a non-zero rank (e.g., rank 1), the third die 115-3 may be configured as having a third predefined die rank being a non-zero rank (e.g., rank 2), and the fourth die 115-4 may be configured as having a fourth predefined die rank being a non-zero rank (e.g., rank 3).

The rank0 memory die may interface directly with the memory controller, while the other non-rank0 memory dies may communicate indirectly with the memory controller via the rank0 memory die. For example, the first die 115-1 may receive a command from the memory controller, decode the command received from the memory controller, and transmit a read signal or a write signal to a corresponding non-rank0 memory die based on the command. Alternatively, if the command is intended for the first die 115-1, the first die 115-1 may perform the operation associated with the command. In addition, the first die 115-1 may process output data received from the corresponding non-rank0 memory die prior to providing the output data to the memory controller.

In addition, the second integrated circuit 105-2 may receive one or more programmed signals from the memory controller that place the one or more dies 115-1 through 115-4 into a particular configuration state. The one or more programmed signals may be fixed or fused signals. The first die 115-1 may decode and/or relay any programmed signals intended for the non-rank0 memory dies to the corresponding non-rank0 memory dies. In addition, the second integrated circuit 105-2 may receive one or more operating mode signals from the memory controller that place the one or more dies 115-1 through 115-4 into a particular operating state. For example, the one or more operating mode signals may include a test mode signal that places one or more dies 115-1 through 115-4 in an operating state for testing (e.g., a test mode), or may include a run mode signal that that places one or more dies 115-1 through 115-4 in a normal operating state. The first die 115-1 may decode and/or relay any operating mode signals intended for the non-rank0 memory dies to the corresponding non-rank0 memory dies. In addition, the second integrated circuit 105-2 may receive one or more configuration mode signals that place the one or more dies 115-1 through 115-4 into a particular configuration state.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

In some implementations, a die stack of the second integrated circuit 105-2 includes the first die 115-1 (e.g., a first memory die) and the second die 115-2 (e.g., a second memory die) arranged on the first die 115-1. The third die 115-3 and the fourth die 115-4 may be further arranged on the second die 115-2 as additional memory dies. The first die 115-1 may include a first logic circuit; a first power amplifier configured to regulate an external supply voltage to a first internal supply voltage having a first target voltage level, and provide the first internal supply voltage to the first logic circuit, wherein the first power amplifier is configured to be biased with a first bias current when enabled; a first shorting circuit configured to receive a first control signal and enable or disable the first power amplifier based on the first control signal; and a first control circuit configured to receive a first programmed signal indicating that the first memory die is configured as a rank0 memory die, and generate the first control signal based on the first programmed signal.

The second die 115-2 may include a second logic circuit; a second power amplifier configured to regulate the external supply voltage to a second internal supply voltage having a second target voltage level, and provide the second internal supply voltage to the second logic circuit, wherein the second power amplifier is configured to be biased with a second bias current when enabled; a second shorting circuit configured to receive a second control signal and enable or disable the second power amplifier based on the second control signal; and a second control circuit configured to receive a second programmed signal indicating that the second memory die is configured as a non-rank0 memory die, and generate the second control signal based on the second programmed signal. The third die 115-3 and the fourth die 115-4 may be similarly configured as described in connection with the second die 115-2. In particular, the dies 115-1 through 115-4 may include similar circuitry, but may be configured based on one or more control signals, one or more programmed signals, one or more configuration mode signals, and/or one or more operating mode signals provided by the memory controller.

The first shorting circuit may include a first shorting switch configured to interrupt a first current path of the first bias current to disable the first power amplifier; and a first bypass switch configured to, based on the first power amplifier being disabled, provide the external supply voltage to the first logic circuit. The second shorting circuit may include a second shorting switch configured to interrupt a second current path of the second bias current to disable the second power amplifier; and a second bypass switch configured to, based on the second power amplifier being disabled, provide the external supply voltage to the second logic circuit.

The first control circuit may provide the first control signal to a control terminal of the first shorting switch and to a control terminal of the first bypass switch. The second control circuit may provide the second control signal to a control terminal of the second shorting switch and to a control terminal of the second bypass switch.

The first programmed signal may be configured to enable the first power amplifier, and the second programmed signal may be configured to disable the second power amplifier. The first programmed signal and the second programmed signal may be generated by the memory controller.

The second control circuit may be configured to provide the second control signal such that the second power amplifier is always disabled. For example, the second programmed signal may be fixed or fused such that the second power amplifier is always disabled.

The first control circuit may receive an operating mode signal, and generate the first control signal based on the operating mode signal. For example, the first control circuit may, based on the operating mode signal having a first signal level, generate the first control signal with an enabled signal level such that the first power amplifier is enabled by the first shorting circuit. The first control circuit may, based on the operating mode signal having a second signal level, generate the first control signal with a disabled signal level such that the first power amplifier is disabled by the first shorting circuit. The first shorting circuit may include a first shorting switch configured to interrupt a first current path of the first bias current to disable the first power amplifier, or provide continuity for the first current path to enable the first power amplifier. Additionally, the first shorting circuit may include a first bypass switch configured to, based on the first control signal having the disabled signal level, provide the external supply voltage to the first logic circuit and, based on the first control signal having the enabled signal level, disconnect the first logic circuit from the external supply voltage. The second shorting circuit may include a second shorting switch and a second bypass switch that has a similar arrangement with respect to the second power amplifier that is described in connection with the first shorting circuit.

In some implementations, each die 105-1, 115-1, 115-2, 115-3, and 115-4 may be configurable into a die stack configuration (e.g., a first die configuration) or a single die configuration (e.g., a second die configuration). Each die 105-1, 115-1, 115-2, 115-3, and 115-4 may include volatile memory; a logic circuit; a power amplifier configured to regulate an external supply voltage to an internal supply voltage having a target voltage level, and provide the internal supply voltage to the logic circuit, wherein the power amplifier is configured to be biased with a bias current when enabled; a shorting circuit configured to receive a control signal and enable or disable the power amplifier based on the control signal; and a control circuit configured to receive a configuration mode signal indicating whether the memory die is configured in the die stack configuration or the single die configuration and generate the control signal based on whether the memory die is configured in the die stack configuration or the single die configuration, wherein the control circuit is configured to generate the control signal with an enabled signal level such that the power amplifier is enabled by the shorting circuit, and wherein the control circuit is configured to generate the control signal with a disabled signal level such that the power amplifier is disabled by the shorting circuit.

As indicated above, FIG. 1 is provided as an example. Other examples may differ from what is described with regard to FIG. 1.

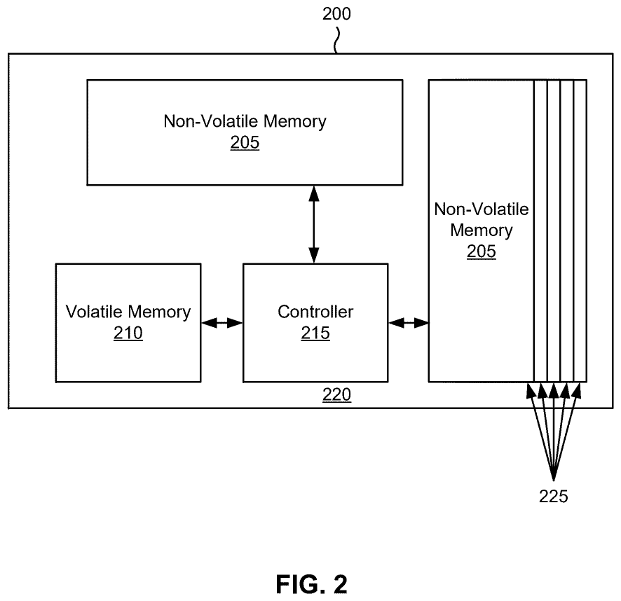

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device. In some implementations, the memory device 200 may be a DDR DIMM.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked memory dies 225 (e.g., in a straight stack, a shingle stack, or another type of stack), as described above in connection with FIG. 1. In some implementations, the volatile memory 210 is provided as a single die. Additionally, or alternatively, the volatile memory 210 may include multiple dies, such as a die stack that includes a plurality of memory dies, including a first memory die (e.g., a rank0 memory die) and at least a second memory die (e.g., at least one non-rank0 memory die) arranged on the first memory die, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. The memory device 200 may include one or more memory interfaces that enable the controller 215 to communicate with the non-volatile memory 205 and the volatile memory 210, including a non-volatile memory interface (e.g., for communicating with non-volatile memory 205), such as a NAND interface or a NOR interface, and/or a volatile memory interface (e.g., for communicating with volatile memory 210), such as a double data rate (DDR) interface.

In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205). In some implementations, the controller 215 may transmit one or more programmed signals to the non-volatile memory 205 and/or the volatile memory 210. In some implementations, the controller 215 may transmit one or more operating mode signals to the non-volatile memory 205 and/or the volatile memory 210. In some implementations, the controller 215 may transmit one or more configuration mode signals to the non-volatile memory 205 and/or the volatile memory 210.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

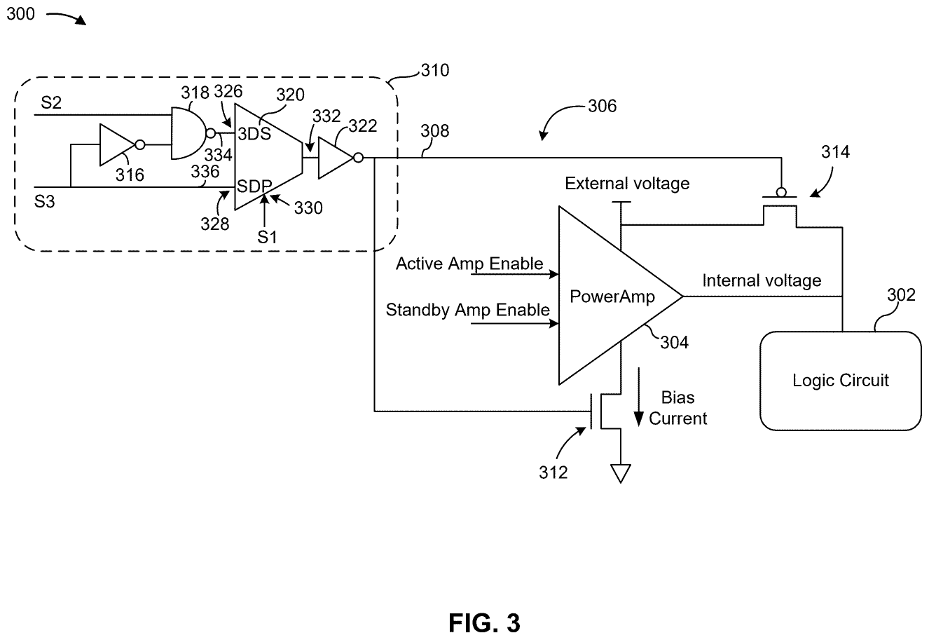

FIG. 3 is a schematic diagram of a memory die 300 according to one or more implementations. The memory die 300 may be or include any of the dies described herein, including die 105-1, 115-1, 115-2, 115-3, or 115-4. The memory die 300 may be a volatile memory die, such as a DRAM die, with volatile memory. The memory die 300 may be configurable into a die stack configuration (e.g., for being implemented in the second integrated circuit 105-2) or a single die configuration (e.g., for being implemented in the first integrated circuit 105-1).

The memory die 300 may include a logic circuit 302 that is used (e.g., is active) when the memory die is used in the single die configuration or as a rank0 memory die in the die stack configuration. For example, the logic circuit 302 may interface with a memory controller. Alternatively, the logic circuit 302 may not be used (e.g., may be inactive) when the memory die is used as a non-rank0 memory die in the die stack configuration.

Additionally, the memory die 300 may include a power amplifier 304 configured to regulate an external supply voltage to an internal supply voltage having a target voltage level, and provide the internal supply voltage to the logic circuit 302. For example, the power amplifier 304 may convert the external supply voltage to a lower supply voltage such that the internal supply voltage is a stable voltage that is immune or substantially immune to external voltage noise. Thus, the internal supply voltage generated by the power amplifier 304 may improve performance of the logic circuit 302 by reducing or eliminating fluctuations in a supply voltage provided to the logic circuit 302. The power amplifier 304 may be biased with a bias current when enabled. The power amplifier 304 consumes power based on the bias current. Thus, the bias current may be referred to as a leakage current when power consumption by the power amplifier 304 is not desired. The power amplifier 304 may receive an active amp enable signal or a standby amp enable signal, which may change a response time of the power amplifier 304. For example, the active amp enable signal may be used to configure the power amplifier to have a fast response to external voltage transients, whereas the standby amp enable signal may be used to configure the power amplifier to have a slow response to external voltage transients.

Additionally, the memory die 300 may include a shorting circuit 306 configured to receive a control signal 308 and enable or disable the power amplifier 304 based on the control signal 308.

Additionally, the memory die 300 may include a control circuit 310 configured to receive a configuration mode signal S1 indicating whether the memory die 300 is configured in the die stack configuration (e.g., 3DS) or the single die configuration (e.g., SDP) and generate the control signal 308 based on whether the memory die 300 is configured in the die stack configuration or the single die configuration. Thus, the control signal 308 may be a selection signal that indicates in which configuration the memory die 300 is implemented. The control circuit 310 may generate the control signal 308 with an enabled signal level such that the power amplifier 304 is enabled by the shorting circuit 306, and the control circuit 310 may generate the control signal 308 with a disabled signal level such that the power amplifier 304 is disabled by the shorting circuit 306. Disabling the power amplifier 304 may disrupt the bias current such that there is no bias current (e.g., no leakage current) when operating the power amplifier 304 is not desired.

The control circuit 310 may receive a programmed signal S2 indicating whether the memory die 300 is configured as a rank0 memory die or a non-rank0 memory die, and generate the control signal 308 based on the memory die 300 being configured in the die stack configuration (e.g., based on the configuration mode signal S1 indicating that the memory die 300 is configured in the die stack configuration) and based on whether the memory die 300 is configured as a rank0 memory die or a non-rank0 memory die (e.g., based on the programmed signal S2). For example, the control circuit 310 is configured to, based on the programmed signal S2 indicating that the memory die 300 is configured as the non-rank0 memory die, generate the control signal 308 such that the power amplifier 304 is disabled by the shorting circuit 306.

The shorting circuit 306 may include a shorting switch 312 and a bypass switch 314. The shorting switch 312 and the bypass switch 314 may be transistor switches. For example, the shorting switch 312 may be an N-channel MOSFET and the bypass switch 314 may be a P-channel MOSFET.

The shorting switch 312 may be configured to, based on the control signal 308, interrupt a current path of the bias current to disable the power amplifier 304, or provide continuity for the current path to enable the power amplifier 304. For example, the control signal 308 may control switching states of the shorting switch 312. The switching states may include an on state and an off state. When the shorting switch 312 is in an off state, the shorting switch 312 may disable the power amplifier 304 by interrupting the current path of the bias current. When the shorting switch 312 is in an on state, the shorting switch 312 may enable the power amplifier 304 by providing continuity for the current path.

In addition, the bypass switch 314 may be configured to, based on the power amplifier 304 being disabled, provide the external supply voltage to the logic circuit 302, and, based on the power amplifier 304 being enabled, disconnect the logic circuit 302 from the external supply voltage. For example, the control signal 308 may control switching states of the bypass switch 314. The switching states may include an on state and an off state. When the bypass switch 314 is in an off state, the bypass switch 314 may disconnect the logic circuit 302 from the external supply voltage by interrupting a supply path between the external supply voltage and the logic circuit 302. When the bypass switch 314 is in an on state, the bypass switch 314 may connect the external supply voltage and the logic circuit 302. The shorting switch 312 and the bypass switch 314 may be configured in complementary switching states. In other words, when the power amplifier 304 is enabled, the power amplifier 304 provides the internal supply voltage to the logic circuit 302, and when the power amplifier 304 is disabled, the bypass switch 314 bypasses the power amplifier 304 in order to provide the external supply voltage to the logic circuit 302.

Providing the external supply voltage to the logic circuit 302 may prevent the logic circuit 302 from being in a floating state (e.g., having a floating ground), which may cause additional power losses, disrupt operations of adjacent circuits, and/or cause uncontrolled and/or unintended operation by the logic circuit 302.

In addition, the control circuit 310 may receive an operating mode signal S3, and generate the control signal 308 based on the operating mode signal S3. The operating mode signal S3 may be used to selectively configure the memory die 300 into a test mode or into a normal operating mode. The control circuit 310 may, based on the operating mode signal S3 having a first signal level (e.g., corresponding to the normal operating mode), generate the control signal 308 with the enabled signal level. The control circuit 310 may, based on the operating mode signal S3 having a second signal level (e.g., corresponding to the test mode), generate the control signal 308 with the disabled signal level. In other words, it may be desired to disable the power amplifier 304 during the test mode in order to perform an evaluation of an operability of the power amplifier 304, the shorting circuit 306, and/or the logic circuit 302.

The control circuit may include a first inverter 316, a NAND gate 318, a multiplexer 320, and a second inverter 322. The multiplexer 320 may include a first input 326, a second input 328, a selection input 330, and an output 332. The selection input 330 may receive the configuration mode signal S1 that indicates whether the memory die 300 is configured in the die stack configuration (e.g., 3DS) or the single die configuration (e.g., SDP). The first input 326 may receive a first control signal 334 based on at least one of the operating mode signal S3 or the programmed signal S2, the programmed signal S2 indicating whether the memory die is configured as a rank0 memory die or a non-rank0 memory die. For example, the first inverter 316 and the NAND gate 318 may be used to generate the first control signal 334 based on the operating mode signal S3 and the programmed signal S2.

The second input 328 may receive the operating mode signal S3 as a second control signal 336. The multiplexer 320 may provide the first control signal 334 at the output 332 based on the selection input 330 receiving the configuration mode signal S1 indicating that the memory die 300 is configured in the die stack configuration. On the other hand, the multiplexer 320 may provide the operating mode signal S3 (e.g., the second control signal 336) at the output 332 based on the selection input 330 receiving the configuration mode signal S1 indicating that the memory die 300 is configured in the single die configuration. The control circuit 310 may, based on the memory die 300 being configured in the die stack configuration, generate the control signal 308 such that the control signal 308 is representative of the first control signal 334. For example, the control signal 308 may be an inverted version of the first control signal 334 based on the first control signal 334 being provided to the second inverter 322. Additionally, the control circuit 310 may, based on the memory die 300 being configured in the single die configuration, generate the control signal 308 such that the control signal 308 is representative of the operating mode signal S3. For example, the control signal 308 may be an inverted version of the operating mode signal S3 based on the operating mode signal S3 being provided to the second inverter 322.

The control circuit 310 may, based on the operating mode signal S3 having the first signal level, based on the configuration mode signal S1 indicating that the memory die 300 is configured in the die stack configuration, and based on the programmed signal S2 indicating that the memory die is configured as the rank0 memory die, generate the control signal 308 with the enabled signal level. The control circuit 310 may, based on the operating mode signal S3 having the first signal level and based on the configuration mode signal S1 indicating that the memory die 300 is configured in the single die configuration, generate the control signal 308 with the enabled signal level. The control circuit 310 may, based on the operating mode signal S3 having the second signal level, based on the configuration mode signal S1 indicating that the memory die 300 is configured in the die stack configuration, and based on the programmed signal S2 indicating that the memory die 300 is configured as the rank0 memory die, generate the control signal 308 with the disabled signal level. The control circuit 310 may, based on the operating mode signal S3 having the second signal level and based on the configuration mode signal S1 indicating that the memory die 300 is configured in the single die configuration, generate the control signal 308 with the disabled signal level. The control circuit may, based on the configuration mode signal S1 indicating that the memory die 300 is configured in the die stack configuration and based on the programmed signal S2 indicating that the memory die 300 is configured as the non-rank0 memory die, disregard the operating mode signal S3 and generate the control signal 308 with the disabled signal level.

Thus, dies 105-1, 115-1, 115-2, 115-3, and 115-4 described in connection with FIG. 1, each including the control circuit 310, may be configured based on the configuration mode signal S1, the programmed signal S2, and/or the operating mode signal S3 to reduce power consumption by disabling the power amplifier 304 and prevent the logic circuit 302 from floating when the power amplifier 304 is disabled.

As indicated above, FIG. 3 is provided as an example. Other examples may differ from what is described with regard to FIG. 3. The number and arrangement of components shown in FIG. 3 are provided as an example. In practice, there may be additional components, fewer components, different components, or differently arranged components than those shown in FIG. 3.

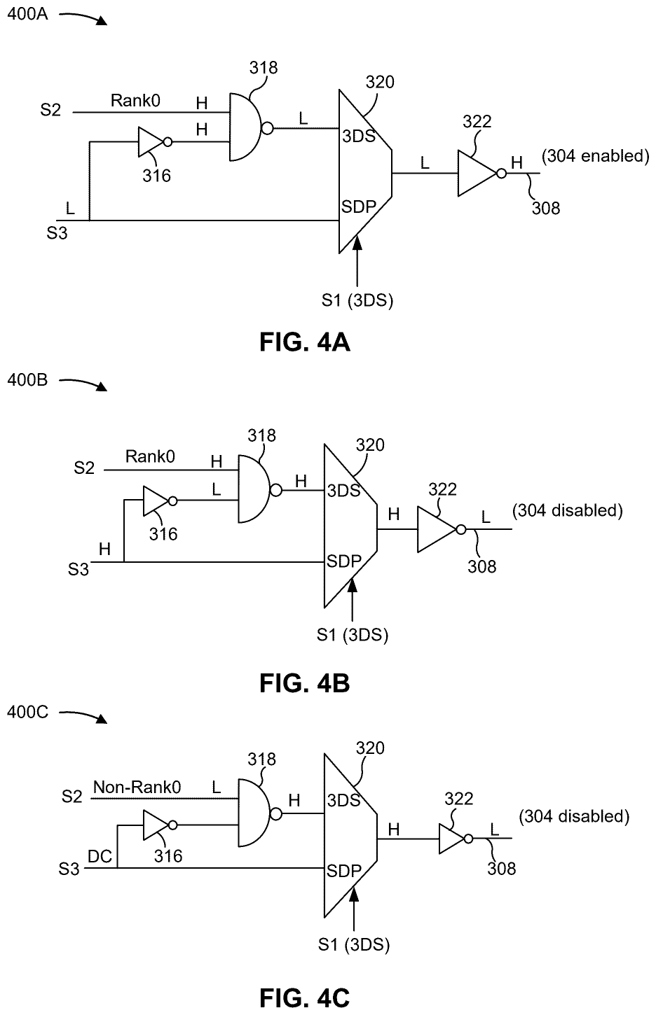

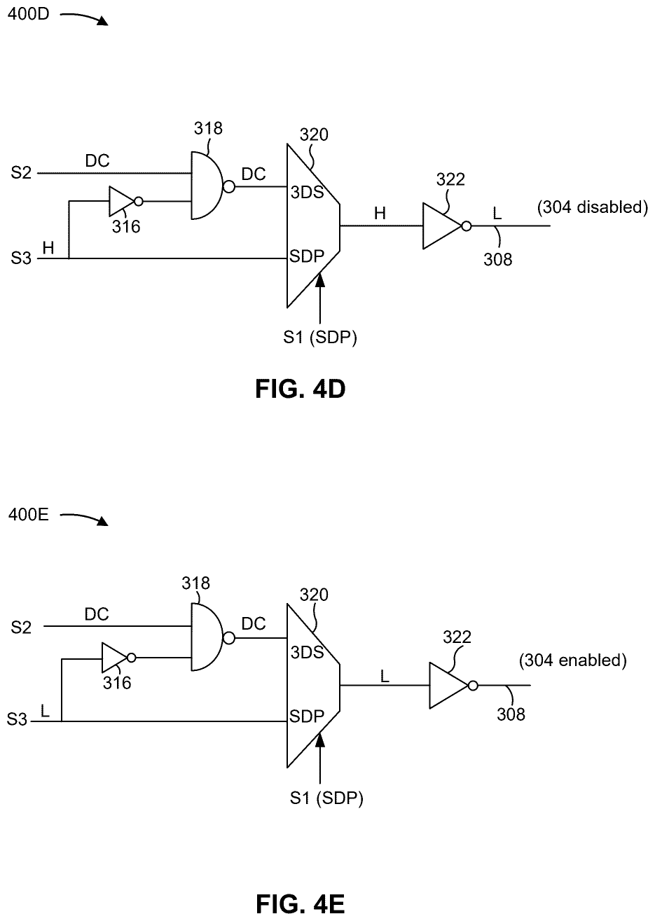

FIG. 4A is a schematic diagram 400A of a control circuit of a memory die according to one or more implementations. The control circuit may be similar to the control circuit 310 described in connection with FIG. 3. An “H” indicates a logic high signal level, an “L” indicates a logic low signal level, and a “DC” indicates a don't care signal level, which means that a signal level may be the logic high signal level or the logic low signal level without affecting the control signal 308.

The schematic diagram 400A may correspond to a memory die being configured in the die stack configuration (e.g., 3DS) as a rank0 memory die. In addition, the memory die may be configured, by the operating mode signal S3, in a non-test mode (e.g. normal operating mode). Thus, the control circuit may, based on the operating mode signal S3 having the first signal level (L), based on the configuration mode signal S1 indicating that the memory die is configured in the die stack configuration, and based on the programmed signal S2 indicating that the memory die is configured as the rank0 memory die (H), generate the control signal 308 with the enabled signal level (H).

As indicated above, FIG. 4A is provided as an example. Other examples may differ from what is described with regard to FIG. 4A.

FIG. 4B is a schematic diagram 400B of a control circuit of a memory die according to one or more implementations. The control circuit may be similar to the control circuit 310 described in connection with FIG. 3.

The schematic diagram 400B may correspond to a memory die being configured in the die stack configuration (e.g., 3DS) as a rank memory die. In addition, the memory die may be configured, by the operating mode signal S3, in a test mode. Thus, the control circuit may, based on the operating mode signal S3 having the second signal level (H), based on the configuration mode signal S1 indicating that the memory die 300 is configured in the die stack configuration, and based on the programmed signal S2 indicating that the memory die 300 is configured as the rank0 memory die, generate the control signal 308 with the disabled signal level (L).

As indicated above, FIG. 4B is provided as an example. Other examples may differ from what is described with regard to FIG. 4B.

FIG. 4C is a schematic diagram 400C of a control circuit of a memory die according to one or more implementations. The control circuit may be similar to the control circuit 310 described in connection with FIG. 3.

The schematic diagram 400C may correspond to a memory die being configured in the die stack configuration (e.g., 3DS) as a non-rank0 memory die. In addition, the memory die may be configured, by the operating mode signal S3, in a test mode or a non-test mode (DC). Thus, the control circuit may, based on the configuration mode signal S1 indicating that the memory die 300 is configured in the die stack configuration and based on the programmed signal S2 indicating that the memory die 300 is configured as the non-rank0 memory die, disregard the operating mode signal S3 and generate the control signal 308 with the disabled signal level (L).

As indicated above, FIG. 4C is provided as an example. Other examples may differ from what is described with regard to FIG. 4C.

FIG. 4D is a schematic diagram 400D of a control circuit of a memory die according to one or more implementations. The control circuit may be similar to the control circuit 310 described in connection with FIG. 3.

The schematic diagram 400D may correspond to a memory die being configured in the single die configuration (e.g., SDP). In addition, the memory die may be configured, by the operating mode signal S3, in a test mode. Thus, the control circuit may, based on the operating mode signal S3 having the second signal level (H) and based on the configuration mode signal S1 indicating that the memory die 300 is configured in the single die configuration, generate the control signal 308 with the disabled signal level.

As indicated above, FIG. 4D is provided as an example. Other examples may differ from what is described with regard to FIG. 4D.

FIG. 4E is a schematic diagram 400E of a control circuit of a memory die according to one or more implementations. The control circuit may be similar to the control circuit 310 described in connection with FIG. 3.

The schematic diagram 400E may correspond to a memory die being configured in the single die configuration (e.g., SDP). In addition, the memory die may be configured, by the operating mode signal S3, in a non-test mode. Thus, the control circuit may, based on the operating mode signal S3 having the first signal level (L) and based on the configuration mode signal S1 indicating that the memory die 300 is configured in the single die configuration, generate the control signal 308 with the enabled signal level.

As indicated above, FIG. 4E is provided as an example. Other examples may differ from what is described with regard to FIG. 4E.

As demonstrated in FIGS. 4A-4E, each die 105-1, 115-1, 115-2, 115-3, and 115-4 described in connection with FIG. 1 may be selectively configured based on the configuration mode signal S1, the programmed signal S2, and/or the operating mode signal S3 to reduce power consumption by disabling the power amplifier 304 when the power amplifier 304 is not used or during a test mode. In addition, each die 105-1, 115-1, 115-2, 115-3, and 115-4 may be selectively configured based on the configuration mode signal S1, the programmed signal S2, and/or the operating mode signal S3 to prevent the logic circuit 302 from floating when the power amplifier 304 is disabled.

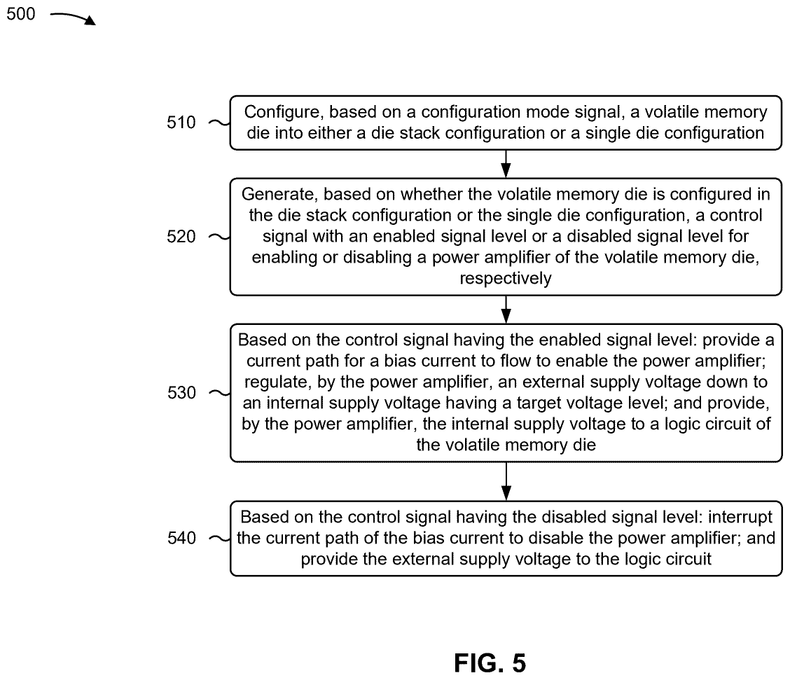

FIG. 5 is a flowchart of an example method 500 associated with a power saving scheme for non-rank0 memory dies. In some implementations, a memory die (e.g., die 105-1, 115-1, 115-2, 115-3, or 115-4) may perform or may be configured to perform the method 500. In some implementations, another device or a group of devices separate from or including the memory die (e.g., controller 215) may perform or may be configured to perform at least part of the method 500. Additionally, or alternatively, one or more components of the memory die (e.g., control circuit 310 and/or shorting circuit 306) may perform or may be configured to perform the method 500. Thus, means for performing the method 500 may include the memory die and/or one or more components of the memory die. Additionally, or alternatively, a non-transitory computer-readable medium may store one or more instructions that, when executed by the memory die, cause the memory die to perform the method 500.

As shown in FIG. 5, the method 500 may include configuring, based on a configuration mode signal, a volatile memory die into either a die stack configuration or a single die configuration (block 510). As further shown in FIG. 5, the method 500 may include generating, based on whether the volatile memory die is configured in the die stack configuration or the single die configuration, a control signal with an enabled signal level or a disabled signal level for enabling or disabling a power amplifier of the volatile memory die, respectively (block 520). As further shown in FIG. 5, the method 500 may include, based on the control signal having the enabled signal level: providing a current path for a bias current to flow to enable the power amplifier; regulating, by the power amplifier, an external supply voltage down to an internal supply voltage having a target voltage level; and providing, by the power amplifier, the internal supply voltage to a logic circuit of the volatile memory die (block 530). As further shown in FIG. 5, the method 500 may include, based on the control signal having the disabled signal level: interrupting the current path of the bias current to disable the power amplifier; and providing the external supply voltage to the logic circuit (block 540).

The method 500 may include additional aspects, such as any single aspect or any combination of aspects described in connection with one or more other methods or operations described elsewhere herein.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

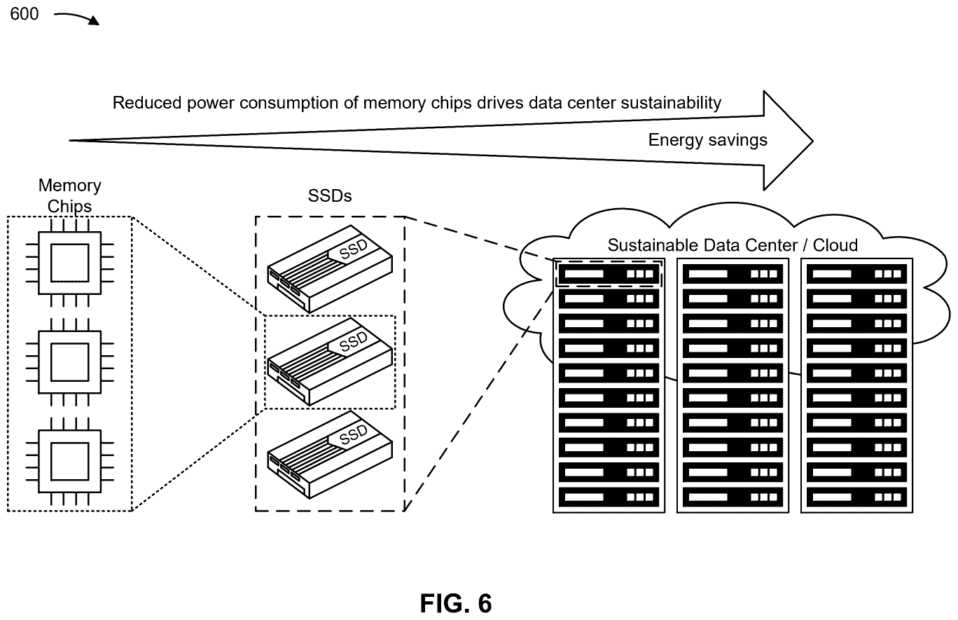

FIG. 6 is a diagram 600 illustrating example systems in which the memory device 200 described herein may be used. In some implementations, one or more memory devices 200 may be included in a memory chip. Multiple memory chips may be packaged together and included in a higher-level system, such as a solid state drive (SSD) or another type of memory drive. Each SSD may include, for example, up to five memory chips, up to ten memory chips, or more. A data center or cloud computing environment may include multiple SSDs to store a large amount of data. For example, a data center may include hundreds, thousands, or more SSDs.

As described above, some implementations described herein reduce power consumption of a memory device 200. As shown in FIG. 6, this reduced power consumption drives data center sustainability and leads to energy savings because of the large volume of memory devices 200 included in a data center.

As indicated above, FIG. 6 is provided as an example. Other examples may differ from what is described with regard to FIG. 6.

In some implementations, a semiconductor device assembly, comprising; a die stack comprising a plurality of memory dies, including a first memory die and a second memory die arranged on the first memory die, wherein the first memory die includes: a first logic circuit; a first power amplifier configured to regulate an external supply voltage to a first internal supply voltage having a first target voltage level, and provide the first internal supply voltage to the first logic circuit, wherein the first power amplifier is configured to be biased with a first bias current when enabled; a first shorting circuit configured to receive a first control signal and enable or disable the first power amplifier based on the first control signal; and a first control circuit configured to receive a first programmed signal indicating that the first memory die is configured as having a first predefined die rank, and generate the first control signal based on the first programmed signal; wherein the second memory die includes: a second logic circuit; a second power amplifier configured to regulate the external supply voltage to a second internal supply voltage having a second target voltage level, and provide the second internal supply voltage to the second logic circuit, wherein the second power amplifier is configured to be biased with a second bias current when enabled; a second shorting circuit configured to receive a second control signal and enable or disable the second power amplifier based on the second control signal; and a second control circuit configured to receive a second programmed signal indicating that the second memory die is configured as having a second predefined die rank different than the first predefined die rank, and generate the second control signal based on the second programmed signal.

In some implementations, a memory die configurable into a die configuration, comprising; a volatile memory; a logic circuit; a power amplifier configured to regulate an external supply voltage to an internal supply voltage having a target voltage level, and provide the internal supply voltage to the logic circuit, wherein the power amplifier is configured to be biased with a bias current when enabled; a shorting circuit configured to receive a control signal and enable or disable the power amplifier based on the control signal; and a control circuit configured to receive a configuration mode signal indicating whether the memory die is configured in a first die configuration or a second die configuration and generate the control signal based on whether the memory die is configured in the first die configuration or the second die configuration, wherein the control circuit is configured to generate the control signal with an enabled signal level such that the power amplifier is enabled by the shorting circuit, and wherein the control circuit is configured to generate the control signal with a disabled signal level such that the power amplifier is disabled by the shorting circuit.

In some implementations, a method includes configuring, based on a configuration mode signal, a volatile memory die into either a first die configuration or a second die configuration; generating, based on whether the volatile memory die is configured in the first die configuration or the second die configuration, a control signal with an enabled signal level or a disabled signal level for enabling or disabling a power amplifier of the volatile memory die, respectively; based on the control signal having the enabled signal level: providing a current path for a bias current to flow to enable the power amplifier; regulating, by the power amplifier, an external supply voltage down to an internal supply voltage having a target voltage level; and providing, by the power amplifier, the internal supply voltage to a logic circuit of the volatile memory die; and based on the control signal having the disabled signal level: interrupting the current path of the bias current to disable the power amplifier; and providing the external supply voltage to the logic circuit.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising;
a die stack comprising a plurality of memory dies, including a first memory die and a second memory die arranged on the first memory die,
wherein the first memory die includes:
a first logic circuit;
a first power amplifier configured to regulate an external supply voltage to a first internal supply voltage having a first target voltage level, and provide the first internal supply voltage to the first logic circuit, wherein the first power amplifier is configured to be biased with a first bias current when enabled;
a first shorting circuit configured to receive a first control signal and enable or disable the first power amplifier based on the first control signal; and
a first control circuit configured to receive a first programmed signal indicating that the first memory die is configured as having a first predefined die rank, and generate the first control signal based on the first programmed signal;
wherein the second memory die includes:
a second logic circuit;
a second power amplifier configured to regulate the external supply voltage to a second internal supply voltage having a second target voltage level, and provide the second internal supply voltage to the second logic circuit, wherein the second power amplifier is configured to be biased with a second bias current when enabled;
a second shorting circuit configured to receive a second control signal and enable or disable the second power amplifier based on the second control signal; and
a second control circuit configured to receive a second programmed signal indicating that the second memory die is configured as having a second predefined die rank different than the first predefined die rank, and generate the second control signal based on the second programmed signal.

2. The semiconductor device assembly of claim 1, wherein the first shorting circuit includes:
a first shorting switch configured to interrupt a first current path of the first bias current to disable the first power amplifier; and
a first bypass switch configured to, based on the first power amplifier being disabled, provide the external supply voltage to the first logic circuit;
wherein the second shorting circuit includes:
a second shorting switch configured to interrupt a second current path of the second bias current to disable the second power amplifier; and
a second bypass switch configured to, based on the second power amplifier being disabled, provide the external supply voltage to the second logic circuit.

3. The semiconductor device assembly of claim 2, wherein the first control circuit is configured to provide the first control signal to a control terminal of the first shorting switch and to a control terminal of the first bypass switch, and
wherein the second control circuit is configured to provide the second control signal to a control terminal of the second shorting switch and to a control terminal of the second bypass switch.

4. The semiconductor device assembly of claim 1, wherein the first programmed signal is configured to enable the first power amplifier, and
wherein the second programmed signal is configured to disable the second power amplifier.

5. The semiconductor device assembly of claim 1, further comprising:
a memory controller configured to generate the first programmed signal and the second programmed signal.

6. The semiconductor device assembly of claim 5, wherein the first memory die is configured to decode a command received from the memory controller and transmit a read signal or a write signal to the second memory die based on the command.

7. The semiconductor device assembly of claim 1, wherein the second control circuit is configured to provide the second control signal such that the second power amplifier is always disabled.

8. The semiconductor device assembly of claim 1, wherein the second programmed signal is fixed such that the second power amplifier is always disabled.

9. The semiconductor device assembly of claim 1, wherein the first control circuit is configured to receive an operating mode signal, and generate the first control signal based on the operating mode signal,
wherein the first control circuit is configured to, based on the operating mode signal having a first signal level, generate the first control signal with an enabled signal level such that the first power amplifier is enabled by the first shorting circuit, and
wherein the first control circuit is configured to, based on the operating mode signal having a second signal level, generate the first control signal with a disabled signal level such that the first power amplifier is disabled by the first shorting circuit.

10. The semiconductor device assembly of claim 9, wherein the first shorting circuit includes:
a first shorting switch configured to interrupt a first current path of the first bias current to disable the first power amplifier, or provide continuity for the first current path to enable the first power amplifier; and
a first bypass switch configured to, based on the first control signal having the disabled signal level, provide the external supply voltage to the first logic circuit and, based on the first control signal having the enabled signal level, disconnect the first logic circuit from the external supply voltage.

11. The semiconductor device assembly of claim 1, wherein the first memory die is a rank0 memory die with the first predefined die rank being a zero rank, and the second memory die is a non-rank0 memory die with the second predefined die rank being a non-zero rank.

12. The semiconductor device assembly of claim 1, wherein the plurality of memory dies are dynamic random-access memory (DRAM) memory dies, and
wherein the semiconductor device assembly is a double data rate (DDR) dual in-line memory module (DIMM).

13. A memory die configurable into a die configuration, comprising;
a volatile memory;
a logic circuit;
a power amplifier configured to regulate an external supply voltage to an internal supply voltage having a target voltage level, and provide the internal supply voltage to the logic circuit, wherein the power amplifier is configured to be biased with a bias current when enabled;
a shorting circuit configured to receive a control signal and enable or disable the power amplifier based on the control signal; and
a control circuit configured to receive a configuration mode signal indicating whether the memory die is configured in a first die configuration or a second die configuration and generate the control signal based on whether the memory die is configured in the first die configuration or the second die configuration,
wherein the control circuit is configured to generate the control signal with an enabled signal level such that the power amplifier is enabled by the shorting circuit, and
wherein the control circuit is configured to generate the control signal with a disabled signal level such that the power amplifier is disabled by the shorting circuit.

14. The memory die of claim 13, wherein the control circuit is configured to receive a programmed signal indicating whether the memory die is configured as a rank0 memory die or a non-rank0 memory die, and generate the control signal based on the memory die being configured in the first die configuration and based on whether the memory die is configured as a rank0 memory die or a non-rank0 memory die.

15. The memory die of claim 14, wherein control circuit is configured to, based on the programmed signal indicating that the memory die is configured the non-rank0 memory die, generate the control signal such that the power amplifier is disabled by the shorting circuit.

16. The memory die of claim 13, wherein the shorting circuit includes:
a shorting switch configured to interrupt a current path of the bias current to disable the power amplifier, or provide continuity for the current path to enable the power amplifier; and
a bypass switch configured to, based on the power amplifier being disabled, provide the external supply voltage to the logic circuit, and, based on the power amplifier being enabled, disconnect the logic circuit from the external supply voltage.

17. The memory die of claim 13, wherein the control circuit is configured to receive an operating mode signal, and generate the control signal based on the operating mode signal,
wherein the control circuit is configured to, based on the operating mode signal having a first signal level, generate the control signal with the enabled signal level, and
wherein the control circuit is configured to, based on the operating mode signal having a second signal level, generate the control signal with the disabled signal level.

18. The memory die of claim 13, wherein the control circuit comprises:
a multiplexer including a first input, a second input, a selection input, and an output,
wherein the first input is configured to receive a first control signal based on at least one of an operating mode signal and a programmed signal, the programmed signal indicating whether the memory die is configured as a rank0 memory die or a non-rank0 memory die,
wherein the second input is configured to receive the operating mode signal as a second control signal,
wherein the multiplexer is configured to provide the first control signal at the output based on the selection input receiving the configuration mode signal indicating that the memory die is configured in the first die configuration,
wherein the multiplexer is configured to provide the operating mode signal at the output based on the selection input receiving the configuration mode signal indicating that the memory die is configured in the second die configuration,
wherein the control circuit is configured to, based on the memory die being configured in the first die configuration, generate the control signal such that the control signal is representative of the first control signal, and
wherein the control circuit is configured to, based on the memory die being configured in the second die configuration, generate the control signal such that the control signal is representative of the operating mode signal.

19. The memory die of claim 18, wherein the control circuit is configured to, based on the operating mode signal having a first signal level, based on the configuration mode signal indicating that the memory die is configured in the first die configuration, and based on the programmed signal indicating that the memory die is configured as the rank0 memory die, generate the control signal with the enabled signal level,
wherein the control circuit is configured to, based on the operating mode signal having the first signal level and based on the configuration mode signal indicating that the memory die is configured in the second die configuration, generate the control signal with the enabled signal level,
wherein the control circuit is configured to, based on the operating mode signal having a second signal level, based on the configuration mode signal indicating that the memory die is configured in the first die configuration, and based on the programmed signal indicating that the memory die is configured as the rank0 memory die, generate the control signal with the disabled signal level,
wherein the control circuit is configured to, based on the operating mode signal having the second signal level and based on the configuration mode signal indicating that the memory die is configured in the second die configuration, generate the control signal with the disabled signal level, and
wherein the control circuit is configured to, based on the configuration mode signal indicating that the memory die is configured in the first die configuration and based on the programmed signal indicating that the memory die is configured as the non-rank0 memory die, disregard the operating mode signal and generate the control signal with the disabled signal level.

20. The memory die of claim 13, wherein the first die configuration is a die stack configuration in which the memory die is arranged in a die stack and a second die configuration is a single die configuration in which the memory die is arranged as a standalone die.

21. A method, comprising:
configuring, based on a configuration mode signal, a volatile memory die into either a first die configuration or a second die configuration;
generating, based on whether the volatile memory die is configured in the first die configuration or the second die configuration, a control signal with an enabled signal level or a disabled signal level for enabling or disabling a power amplifier of the volatile memory die, respectively;
based on the control signal having the enabled signal level:
providing a current path for a bias current to flow to enable the power amplifier;
regulating, by the power amplifier, an external supply voltage down to an internal supply voltage having a target voltage level; and
providing, by the power amplifier, the internal supply voltage to a logic circuit of the volatile memory die; and
based on the control signal having the disabled signal level:
interrupting the current path of the bias current to disable the power amplifier; and
providing the external supply voltage to the logic circuit.
